(19) United States
(12) Patent Application Publication
(10) Pub. No.: US 2014/0254835 A1
(43) Pub. Date: Sep. 11, 2014

(54) Packaged Microphone System with a Permanent Magnet

(71) Applicant: ANALOG DEVICES, INC., Nonwood, MA (US)

(72) Inventor: James P. Yakura, Colorado Springs, CO (US)

(73) Assignee: ANALOG DEVICES, INC., Norwood, MA (US)

(21) Appl. No.: 13/785,610

(22) Filed: Mar. 5, 2013

(51) Int. Cl. H04R 23/00; H04R 31/00; H03F 3/181

(52) U.S. Cl. CPC H04R 23/00; H03F 3/181; H04R 31/006
USPC 381/120; 381/174; 29/594

(57) ABSTRACT

A microphone structure has a lid forming an interior chamber. The lid includes a permanent magnet for forming a permanent magnetic field. The microphone structure includes an aperture for permitting acoustic access to the interior of the chamber and thus, the MEMS microphone. The MEMS microphone structure includes a substrate mechanically coupled to an electrically conductive diaphragm. The electrically conductive diaphragm has a first side defining a plane and the diaphragm moves through a range of motion perpendicular the plane of the first side. The permanent magnetic field is perpendicular to the direction of motion of the diaphragm and linear within the range of motion, such that a current will be generated and sensed by sensors within an electric circuit loop that includes the diaphragm.

### FIELD OF THE INVENTION

The invention generally relates to acoustic devices and, more particularly, the invention relates to MEMS acoustic devices and circuitry associated with MEMS acoustic devices.

### BACKGROUND OF THE INVENTION

MEMS microphones typically are secured within an interior chamber of a package to protect them from the environment. An integrated circuit chip, also mounted within the interior chamber and having active circuit elements, processes electrical signals to and from the microphone. One or more apertures through some portion of the package permit acoustic signals to reach the microphone. Receipt of the audio signal causes the microphone, with its corresponding integrated circuit chip, to produce an electronic signal representing the audio qualities of the received signal.

Presently MEMS microphones are generally variants of the condenser and piezoelectric microphone design. The condenser microphones measure changes in capacitance between a diaphragm that moves in the presence of an audio signal and a fixed backplate. Thus, the change in capacitance between the backplate and the diaphragm represents the audio signal. Piezoelectric microphone designs use the phenomenon of piezoelectricity wherein a material produces a voltage when subjected to a pressure to convert vibrations of a diaphragm into an electrical signal.

### SUMMARY OF VARIOUS EMBODIMENTS

In accordance with one embodiment of the invention, a microphone system includes a substrate and an electrically-conductive diaphragm having a surface defining a plane suspended above the substrate moveable in a direction substantially perpendicular to the surface of the diaphragm and having a range of motion. The microphone system further includes a lid including a permanent magnet, lid creating a magnetic field substantially parallel and linear to the surface of the diaphragm at least within the range of motion. The microphone system also includes a plurality of sensors for sensing a resultant current due to the electrically conductive diaphragm moving through the permanent magnetic field. The microphone system may be a microelectromechanical structure (MEMS).

The substrate may include one or more voids allowing air to pass through the substrate. The microphone system may include a plurality of springs coupled to the diaphragm defining and restricting the range of motion of the diaphragm. The system may also include a suspension structure mechanically coupled to the plurality of springs. The springs may be serpentine springs. The plurality of springs from opposite sides of the diaphragm may comprise an electrical current path through the diaphragm. The system may also include an amplifier circuit for amplifying the resultant current and electrically coupled to the microphone system. The system may include a primary circuit die electrically coupled to the substrate and within the lid. Embodiments of the system may also include a passive circuit die electrically coupled to the substrate and within the lid.

In embodiments of the invention, the lid is entirely a permanent magnet. In other emboidments, the lid includes a plurality of permanent magnets. The permanent magnet generates a permanent magnetic field having field lines wherein at least some of the field lines are parallel to the diaphragm through the range of motion.

In other embodiments of the invention, the substrate includes a magnetic element and the lid includes a magnetic element wherein the magnetic element of the substrate and the magnetic element of the lid are attractive. In methods for creating a MEMS microphone package one or more magnetic elements having a first state are added to a periphery of a substrate. A diaphragm is positioned above the backplate. A lid having one or more magnetic elements having a second state attractive to the first state is placed proximate to the magnetic elements in the substrate. The methodology may further include the creation of one or more voids within the substrate allowing air to pass through the substrate. A layer may be added to the substrate to create a support structure. A plurality of serpentine springs coupled to the support structure to the diaphragm may be etched.

Methodology for the creation of a MEMS microphone structure is also disclosed. First, the substrate itself is planarized to form a top surface. A diaphragm is positioned above the substrate, the diaphragm being mechanically coupled to the substrate and having a range of movement substantially perpendicular to the top surface of the substrate. A lid including a permanent magnetic creating a permanent magnetic field is placed over the diaphragm positioned such that the permanent magnetic field is substantially parallel to the diaphragm through the range of movement of the diaphragm. One or more voids are created within the substrate allowing air to pass through the substrate. A layer may be added to the substrate to create a support structure for supporting the diaphragm. The diaphragm may be coupled to the support structure by means of a plurality of springs.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a perspective view of a packaged microphone that may implement illustrative embodiments of the invention.

FIG. 2 schematically shows a cross-sectional view of the packaged microphone in FIG. 1 across line 4-4.

FIG. 3A schematically shows a perspective view of a MEMS microphone that may be used with illustrative embodiments of the invention.

FIG. 3B schematically shows a cross-sectional view of the MEMS microphone of FIG. 3A across line B-B. FIG. 4A shows a side view of an exemplary MEMS microphone structure with a permanent magnet in the lid and the audio signal originating from below and passing through the substrate to the diaphragm.

FIG. 4B shows another side view of an exemplary MEMS microphone structure with a permanent magnet in the lid and a representation of the B-field.

FIG. 5 shows a side view of an exemplary MEMS microphone structure that includes a permanently magnetized lid and a ferromagnetic region of a substrate for forming a seal between the substrate and the lid of the MEMS microphone structure.

### DESCRIPTION OF ILLUSTRATIVE EMBODIMENTS

Illustrative embodiments of the present invention employ a permanent magnet as part of the encapsulating structure for a MEMS device. Permanent magnets have persistent magnetic fields caused by ferromagnetism. In certain embodiments, the conductive microphone diaphragm moves through a magnetic field in response to changes in pressure associated with the incoming sound/acoustic waves. The charged particles within the electrically conductive microphone diaphragm will experience an electromotive force as the diaphragm moves through the field of the permanent magnet appearing as an electrical potential across the diaphragm. This electrical potential may be used to drive the charged particles producing a current through the diaphragm and its associated circuitry. This current is therefore proportional to the movement of the conductive diaphragm through the magnetic field. Thus, a MEMS microphone device does not need to have a backplate and is less prone to stiction compared to condenser microphones.

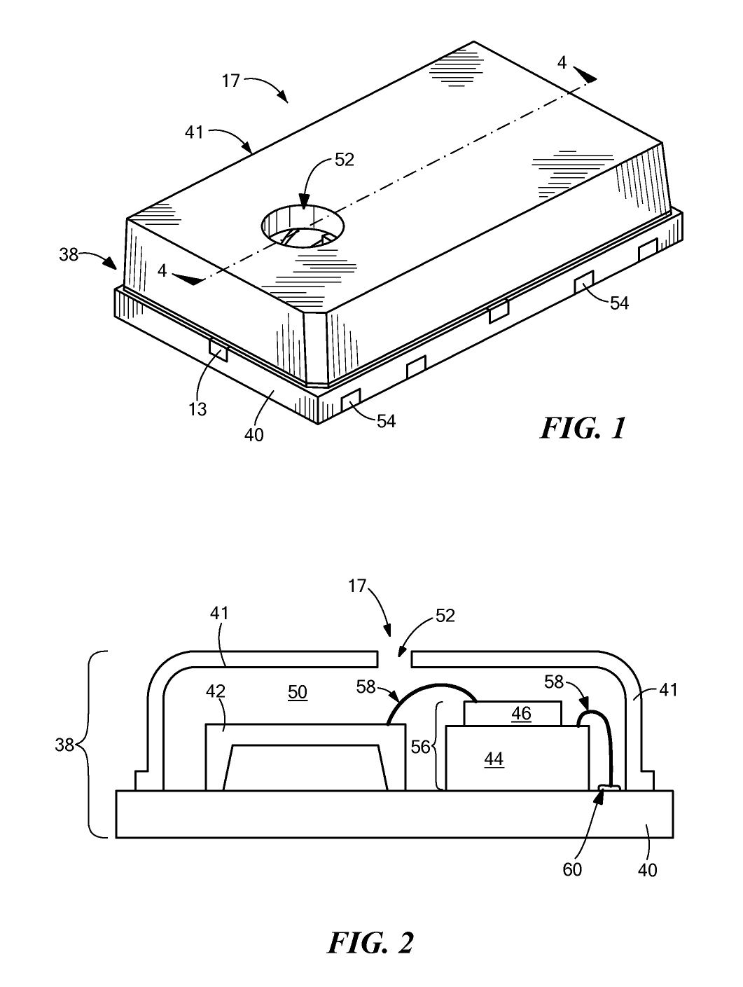

In illustrative embodiments, a MEMS microphone is shown. FIG. 1 schematically shows a packaged microphone system 17 (also referred to as a “microphone system 17” or “packaged microphone 17”) implemented in accordance with illustrative embodiments of the invention. The packaged microphone 17 has a package 38 that may be coupled with an underlying apparatus, such as a printed circuit board. The underlying apparatus, however, can comprise any of a variety of other devices (e.g., other integrated circuits). Accordingly, discussion of a printed circuit board is illustrative and not intended to limit a variety of other embodiments.

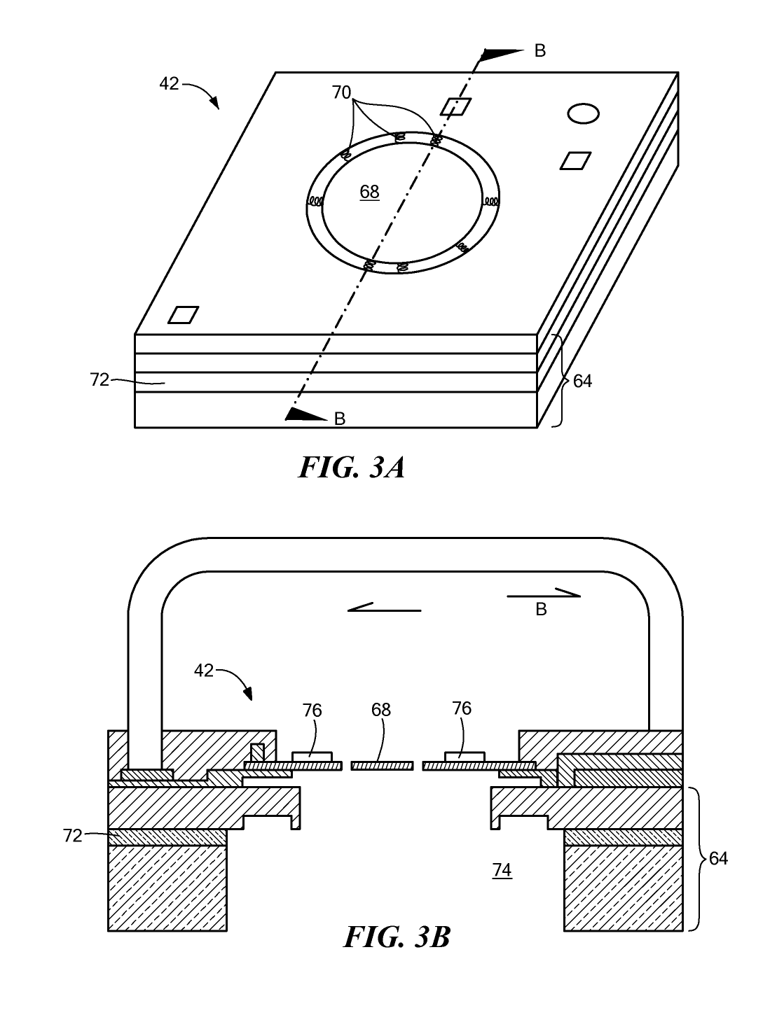

The package 38 has a base 40 (sometimes referred to by those in the art as a “substrate”) that, together with a corresponding lid 41, forms an interior chamber 50 containing a microelectromechanical system microphone die 42 (discussed in detail below with regard to FIG. 2, also known as a “MEMS microphone” or “silicon microphone”) for receiving and converting acoustic signals and may also include one or more chips for controlling signals within the system 17. The general function of the circuit die 44 is to control and manage input to and output from the microphone die 42 (also referred to as a “microphone chip 42”). For example, among other things, the circuit chip 44 may amplify varying signals produced by the microphone die 42, and control the bias applied to the microphone die 42. In illustrative embodiments, the circuit chip 44 is implemented as an application specific integrated circuit, which is also known as an “ASIC.”

Some embodiments may have an integrated passive device (“IPD 46), which provides additional functionality to the microphone system 17. Among other things, those functions may include:
1. the ability to program the system,
2. to implement at least part of the programs described above for the hearing instruments,
3. enable more effective circuit trimming, facilitate lot tests,
4. enable better lot tracing,
5. radio frequency filtering (RF filtering) to reduce electromagnetic interference (“EMI”),
6. circuit coupling and decoupling,
7. impedance matching, and
8. power division.

As known by those skilled in the art, an IPD 46 typically is an integrated circuit having passive circuit elements only—namely, resistors, capacitors, and inductors. Illustrative embodiments may position active elements (e.g., operational amplifiers having transistors) outside of the IPD 46. For example, the primary circuit die 44 may have a plurality of active elements, as well as some passive elements, implementing an operational amplifier (i.e., an “op-amp”).

Because microphones dies/chips 42 can be susceptible to EMI, the package 38 preferably incorporates noise reducing technology. This noise reducing technology is in addition to, or instead of, RF filtering that may be implemented by the IPD 46. Accordingly, illustrative embodiments effectively form a Faraday cage around the microphone die 42 in any of a number of different manners. To that end, the lid 41 in the embodiments shown is a cavity-type, solid metal lid having four walls extending generally orthogonally from a top, interior face. As solid metal, the lid 41 does not require a metal coating on a plastic or other base material. Instead, illustrative embodiments form the lid 41 from a piece of metal, such as a piece of sheet metal. For example, in illustrative embodiments, the lid 41 is a formed metal lid having a generally cup-shaped concavity defining a part of the package chamber 50. The lid 41 secures to the top face of the substantially flat package base 40 to form the interior chamber 50. Walls formed from both the lid 41 and base 40, in any dimension, may be considered to define the chamber 50.

Other types of metal lids may be used. For example, the lid 41 may be flat and coupled to upwardly projecting walls extending from the base 40. It should be understood by one of ordinary skill in the art that a lid should be understood to be part of an LGA (land grid array) cavity package or an SOIC (small outline integrated circuit) package.

Preferably, the lid is magnetized. The lid be magnetized prior to assembly or post assembly. The lid should be constructed at least in part from a ferromagnetic material such as iron, nickel and other rare earth metals. The lid may be magnetized by passing the lid through a permanent magnetic field in order to make the lid into a permanent magnet or other methods of magnetization may be used. For example, the lid may be heated to a high temperature and then cooled while in a magnetic field in order to cause the domains of the material to align and create a permanent magnetic field. All or a portion of the lid may be magnetized so long as a B-field is created. Preferably the B-field internal to the lid has one or more regions that produce a linear or substantially linear field in proximity to the movable diaphragm of the microphone.

The lid 41 also has an audio input port 52 (also referred to as an aperture 52) that enables ingress of audio signals into the chamber 50. In alternative embodiments, however, the audio port 52 is at another location, such as through another portion of the top face of the lid 41, the side of the lid 41 (discussed below), or through the base 40. Some embodiments may have multiple input ports 52 (e.g., a directional microphone).

Conventional techniques can be used to connect the lid 41 to the base 40. For example, after mounting the internal dies 42, 44, and 46 within the package chamber 50, conventional fabrication processes can connect the lid 41 to the base 40 with an adhesive. Conductive adhesive preferably is used to ensure that the lid 41 has the same potential as prescribed portions of the base 40. To that end, the base 40 may have a bond pad 13 that directly contacts the lid 41 to provide such a same potential. Alternative embodiments may use a non-conductive adhesive, a solder, or other adhering medium used in the art.

In another embodiment of the invention, the lid and the base to which the lid attaches, include permanent magnets or a permanent magnet and a ferromagnetic material. The magnet of the base and the magnet of the lid are selected, such that the lid and base are attractive. Thus, the lid may be secured to the base through a magnetic coupling and not require the use of adhesive, epoxy or soldering. By eliminating adhesive, epoxy and soldering additional processing steps are eliminated in the construction of the microphone package and the contamination to the device that can occur during the processing.

Audio signals entering the interior chamber 50 interact with the microphone die 42 and, consequently, the primary circuit die 44, to produce an electrical output signal. Moreover, depending on its function, the IPD 46 also may cooperate with the primary circuit die 44 and microphone die 42 to produce an electrical output signal. Specifically, acoustic signals contact the microphone die 42, which converts this acoustic signal into an electric signal. This electric signal is directed toward the primary circuit die 44 for processing. As explained in further detail below, the electrical output signal is generated by the diaphragm of the die moving through the permanent magnetic field of the lid, the charges within said diaphragm experiencing a Lorentz force producing a current signal through the MEMS sensor.

The bottom face of the package base 40 has a number of external contacts/bond pads 54 for electrically (and physically, in many anticipated uses) connecting the microphone system 17 with an external apparatus (not shown but noted above), such as a printed circuit board or other electrical interconnect apparatus of the next level device (e.g., of a hearing instrument or mobile device). In illustrative embodiments, the package 38 is surface mounted to the circuit board. Accordingly, during use, the microphone die 42, IPD 46 (if used in that capacity), and primary circuit die 44 cooperate to convert audio signals received through the aperture 52 into electrical signals, and route those signals through external contacts/bond pads 54 in the base 40 to the circuit board.

In illustrative embodiments, the package base 40 is formed from an electrical interconnect apparatus, such as a ceramic package material, carrier, printed circuit board material (e.g., using alternating layers of FR-4 or a bismaleimide-triazine resin laminate-type material). Other types of packages may be used, however, such as premolded, leadframe-type packages (also referred to as a “premolded package”). As suggested above, the base 40 may be a cavity package, or a flat-type package.

FIG. 2 schematically shows a cross-sectional view of the packaged microphone 17 of FIG. 1. To reduce space requirements within the package chamber 50, the primary circuit die 44 and the optional IPD 46 are positioned on the base 40 (considered a wall of the chamber 50) in a stacked configuration adjacent to the microphone die 42. In other words, as shown, the primary circuit die 44 and IPD 46 share at least one vertical plane from the perspective of the drawings. For example, the general centers of the two chips 20 and 22 may be substantially aligned in the vertical direction. In this case, they also are physically and electrically connected. Accordingly, in this embodiment, the IPD 46 and primary circuit die 44 thus may be considered to be a single unit (sometimes referred to herein as a “stack 56”), both logically and physically.

Specifically, both electrically cooperate to manage signals and power, among other things, within the package 38, thus logically functioning as a single unit. In a similar manner, since they are secured to each other in a stacked configuration (e.g., using a flip chip connection), they may be considered to be a single physical unit.

The stack 56 and the microphone die 42 preferably are closely positioned within the package interior and electrically connected with one or a plurality of wire bonds 58. The wire bond 58 illustratively extends between bond pads (not shown) on the primary circuit die 44 and the microphone die 42. In other embodiments, the microphone die wire bond 58 directly connects with internal pads 60 on the base 40. In both cases and in other cases, one or more wire bonds 58 may extend from pads on the stack 56 (e.g., from pads on the primary circuit die 44) to the interior pads 60 exposed on the base 40. These interior pads 60 connect with the exterior pads 54 to provide the requisite electrical communication with external devices.

Although FIG. 2 shows the IPD 46 on top of the primary circuit die 44 (from the perspective of the drawing), alternative embodiments may position the primary circuit die 44 on top of the IPD 46. In such alternative embodiments, the IPD 46 may be secured directly to the base 40, and support the primary circuit die 44. Again, both dies are electrically and physically connected. Moreover, the IPD 46 may be larger or smaller than the primary circuit die 44 in one or more dimensions. In yet other embodiments, the microphone system 17 has a plurality of IPDs 46, and/or a plurality of primary circuit dies either in a stacked configuration, not in a stacked configuration, or both (of course, using multiple dies of the two different types).

Although not shown in the drawings, some embodiments may position both the IPD 46 and primary circuit die 44 on the base 40. In that case, the microphone system 17 has other electrical interconnection means, such as wire bonds 58 between the IPD 46 and the primary circuit die 44. In a similar manner, the microphone die 42 may communicate with the IPD 46 and primary circuit die 44 using one or more wire bonds 58.

In some embodiments, the microphone die 42 may be the only circuitry on the base 40 and with the lid. As previously mentioned, the lid includes a permanent magnet that produces a constant B-field. Operation of the microphone diaphragm in the presence of the B-field will be explained below.

Some embodiments form the aperture 52 through the base 40. In that case, the microphone die 42 may be positioned directly over the aperture 52 (to maximize back volume), or next to the aperture 52.

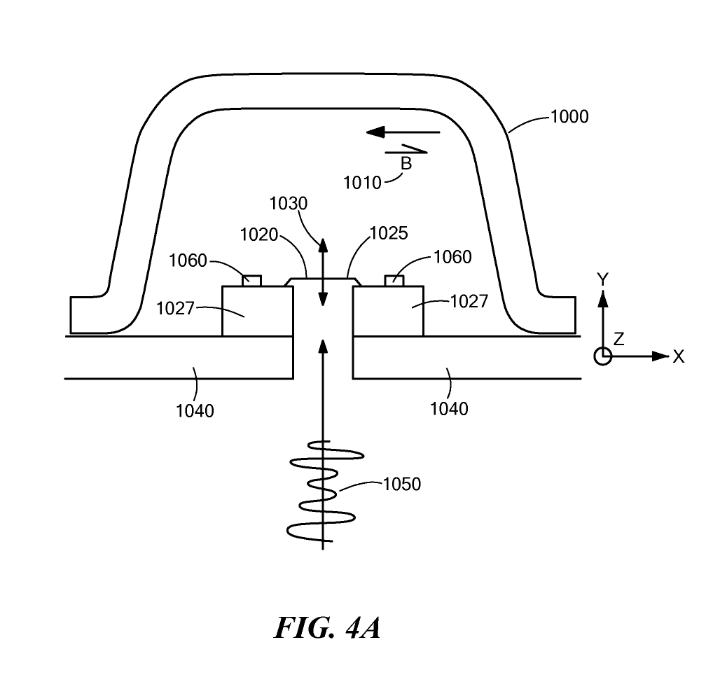

The microphone die 42 may implement any of a number of different types of microphone dies. For example, as suggested above, the microphone die 42 may be implemented as a MEMS microphone die. To that end, FIG. 3A schematically shows a top, perspective view of a MEMS microphone die 42 that may be used with illustrative embodiments of the invention. FIG. 3B schematically shows a cross-sectional view of the same MEMS microphone die 42. These two figures are discussed simply to detail some exemplary components that may make up a microphone die 42 used in accordance with various embodiments. As shown in FIGS. 3A and 3B, the microphone die 42 has a chip base/substrate 64. The microphone die 42 also includes a flexible diaphragm 68 that is suspended by springs 70 above the substrate, and movable relative to the lid (not shown). In an illustrative embodiment, the diaphragm 68 is formed from deposited polysilicon and the diaphragm is electrically conductive.

In the embodiment shown in FIGS. 3A and 3B, the substrate 64 includes other structures, such as a bottom wafer and a buried oxide layer 72 of a silicon-on-insulator (i.e., a SOI) wafer. A portion of the substrate 64 also forms a backside cavity 74 extending from the bottom of the substrate 64 to the bottom of the diaphragm 68.

In operation, as generally noted above, audio/acoustic signals strike the diaphragm 68, causing it to vibrate substantially about the Y-axis. Such audio signals may contact the microphone die 42 from any direction. For example, the audio signals may travel upward, first through the backside cavity, and then partially through and against the diaphragm 68. In other embodiments, the audio signals may travel in the opposite direction.

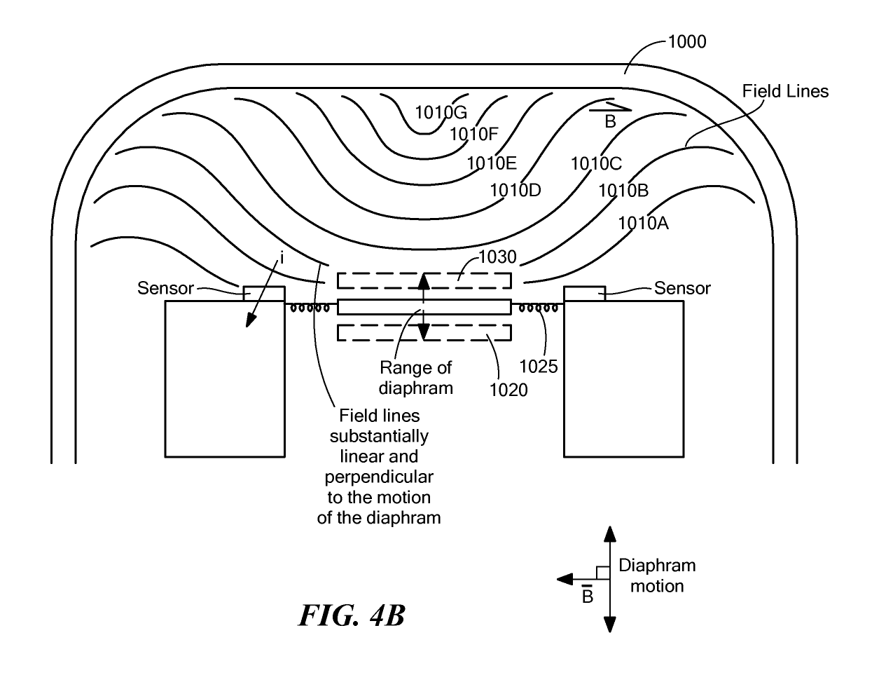

FIGS. 4A and 4B show exemplary side views of a MEMS microphone that includes an electromagnetic lid 1000. Preferably the electromagnetic lid is a permanent magnet, but any magnetic structure that creates a magnetic B field that is substantially linear through the range of motion of the diaphragm 1010A, 1010B and perpendicular to the motion 1030 of the diaphragm 1025 can be used. The magnetic field 1010 can be non-linear and non-perpendicular in regions outside of the motion of the diaphragm 1010C-G. The MEMS microphone with a permanent magnet operates using the following principles. A charged particle in motion in a magnetic field 1010 experiences force at right angles to its velocity with a magnitude proportional to the charge, the velocity, and the magnetic flux density. The force can be represented by the following equation:

F=QV×B

Where:

Q=the charge

V=velocity

B=magnetic field

This force will cause the charged particle to move in a direction perpendicular to both the magnetic field and the diaphragm velocity.

As an audio signal is produced 1050 and the air is moved accordingly through voids created in the substrate, past the support structure 1027 and contacting the diaphragm 1020. The audio signal causes the diaphragm 1020 to move in a substantially linear motion 1030 in the Y-direction as shown. The diaphragm 1020 is supported by springs (e.g. serpentine springs) 1025 that may be electrically conductive and form portions of the sensing circuit. The springs are attached to the support structure 1027 or directly to the substrate. The diaphragm 1020, the springs 1025, and electrodes 1060 form the sensor series elements in an electrical circuit. The electric current flowing through this series of elements is proportional to the velocity of the diaphragm in response to the sonic input and the strength of the magnetic field 1010 perpendicular to the velocity of the diaphragm. Since the motion of the diaphragm is substantially in the Y direction and the permanent magnetic field is substantially perpendicular (in the X direction) to the motion of the diaphragm and linear within the range of motion of the diaphragm 1030, a force field F is generated. As is well known in the art, electricity and magnetism are coupled and therefore a change in a magnetic field will cause a corresponding change in an electric field. The coupling effect is known as electromagnetic induction. The sensing electrodes 1060 sense a current that results from the changes in the corresponding electric field. The sensed current is in the Z direction such that it is perpendicular to both the motion of the diaphragm and the B-field. The sensors are electrically coupled together through the diaphragm 1020 by means of one or more electrically conducting springs 1025. The two sensors, which may be electrodes are positioned on either side of the diaphragm to complete a circuit allowing current to flow. The resultant current represents the audio signal and can be amplified using an amplifier that may be internal or external to the MEMS microphone structure.

It should be recognized that if all or portion of the lid is constructed as a permanent magnet that the resulting B field will not be in a single defined direction (i.e. along the X axis) at all points and will be influenced by the shape of the magnet(s) in the lid. The field will be a vector field that will have both a magnitude and a direction at any particular location. Thus, the lid is preferably shaped and sized so that the vector field is significantly linear in the X direction about the small range of motion 1030 of the diaphragm 1020.

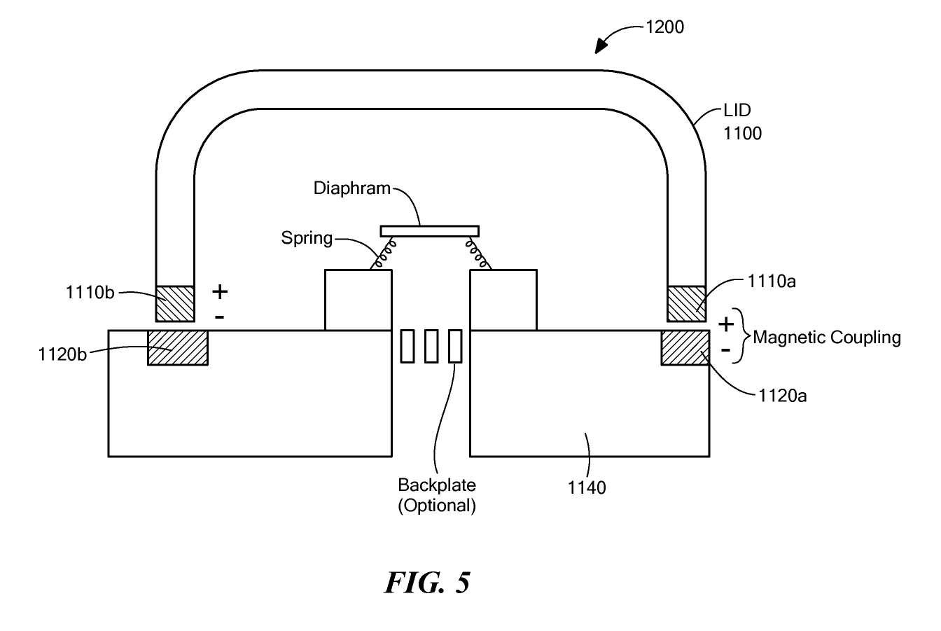

FIG. 5 shows a lid 1100 of an exemplary MEMS microphone structure 1200 wherein the substrate 1140 and the lid 1100 each include magnetic elements (1120a,b and 1110a,b respectively) that are and attractive. By incorporating magnets/ferromagnetic elements in the substrate of the device (1020a,b), these magnets (1020a,b)can be used for securing the lid 1200 to the substrate 1140 without the need for adhesive, epoxy or welding. The magnets 1110a,b and 1120a,b shown in FIG. 5 may be used either alone or in conjunction with the permanent magnetic lid described in previous embodiments.

Although the above discussion discloses various exemplary embodiments of the invention, it should be apparent that those skilled in the art can make various modifications that will achieve some of the advantages of the invention without departing from the true scope of the invention.

What is claimed is:

1. A MEMS microphone comprising:
a substrate;
an electrically-conductive diaphragm having a surface defining a plane suspended above the substrate moveable in a direction substantially perpendicular to the surface of the diaphragm and having a range of motion;
a lid including a permanent magnet, the lid creating a magnetic field substantially parallel and linear to the surface of the diaphragm at least within the range of motion; and
a plurality of sensors for sensing a resultant current due to the electrically conductive diaphragm moving through the permanent magnetic field.

2. A MEMS microphone according to claim 1 wherein the substrate includes one or more voids allowing air to pass through the substrate.

3. A MEMS microphone according to claim 1 further comprising:
a plurality of springs coupled to the diaphragm defining and restricting the range of motion of the diaphragm.

4. A MEMS microphone according to claim 3 further comprising:
a suspension structure mechanically coupled to the plurality of springs.

5. A MEMS microphone according to claim 1, wherein the plurality of springs are serpentine springs.

6. A MEMS microphone according to claim 1, further comprising:
an amplifier circuit for amplifying the resultant current and electrically coupled to the sensors.

7. A MEMS microphone according to claim 1 further comprising a primary circuit die electrically coupled to the substrate and within the lid.

8. A MEMS microphone according to claim 7 further comprising a passive circuit die electrically coupled to the substrate and within the lid.

9. A MEMS microphone according to claim 1, wherein the lid is entirely a permanent magnet.

10. A MEMS microphone according to claim 1, wherein the lid includes a plurality of permanent magnets.

11. A MEMS microphone according to claim 1, wherein the magnetic field includes a plurality of field lines and at least some of the field lines are parallel to the diaphragm through the range of motion.

12. A MEMS microphone according to claim 1 wherein the substrate includes a magnetic element and the lid includes a magnetic element wherein the magnetic element of the substrate and the magnetic element of the lid are attractive.

13. A method for the creation of a MEMS microphone package:
adding one or more magnetic elements having a first state to a periphery of a substrate;
positioning a diaphragm above a backplate; and
placing a lid having one or more magnetic elements having a second state attractive to the first state proximate to the magnetic elements in the substrate.

14. A method according to claim 13, further comprising:
creating one or more voids within the substrate allowing air to pass through the substrate.

15. A method according to claim 14, further comprising:
adding a layer to the substrate to create a support structure.

16. A method according to claim 15, further comprising:
etching a plurality of serpentine springs coupling the support structure to the diaphragm.

17. A method for the creation of a MEMS microphone package:
planarizing a substrate to have a top surface forming a plane;
positioning a diaphragm above the substrate, the diaphragm being mechanically coupled to the substrate and having a range of movement substantially perpendicular to the top surface of the substrate; and
placing a cap including a permanent magnetic creating a permanent magnetic field over the diaphragm positioned such that the permanent magnetic field is substantially parallel to the diaphragm through the range of movement of the diaphragm.

18. A method according to claim 17, further comprising:
creating one or more voids within the substrate allowing air to pass through the substrate.

19. A method according to claim 18, further comprising:
adding a layer to the substrate to create a support structure.

20. A method according to claim 20, further comprising:
etching a plurality of serpentine springs coupling the support structure to the diaphragm.
